(19) United States
(12) Patent Application Publication
(10) Pub. No.: US 2010/0266752 A1
(43) Pub. Date: Oct. 21, 2010

(54) METHOD FOR FORMING CIRCUIT BOARD STRUCTURE OF COMPOSITE MATERIAL

(76) Inventors: Tzyy-Jang Tseng, Hsinchu City (TW); Cheng-Po Yu, Taoyuan County (TW); Wen-Fang Liu, Taoyuan County (TW)

Correspondence Address: NORTH AMERICA INTELLECTUAL PROPERTY CORPORATION, P.O. BOX 506, MERRIFIELD, VA, 22116, US

(21) Appl. No.: 12/763,224

(22) Filed: Apr. 20, 2010

(30) Foreign Application Priority Data
Apr. 20, 2009 (TW) 098113029

(51) Int. Cl. H05K 3/10

(52) U.S. Cl. 427/97.3

(57) ABSTRACT

A method for forming a circuit board structure of composite material is disclosed. First, a composite material structure including a substrate and a composite material dielectric layer is provided. The composite material dielectric layer includes a catalyst dielectric layer contacting the substrate and at least one sacrificial layer contacting the catalyst dielectric layer. The sacrificial layer is insoluble in water. Later, the composite material dielectric layer is patterned and simultaneously catalyst particles are activated. Then, a conductive layer is formed on the activated catalyst particles. Afterwards, at least one sacrificial layer is removed.

### BACKGROUND OF THE INVENTION

1. Field of the Invention

The method of the present invention generally relates to a method for forming a circuit board structure of composite material. In particular, the method of the present invention is directed to a composite material including a catalyst particle to facilitate the formation of a circuit board structure.

2. Description of the Prior Art

A circuit board is an essential element in an electronic device. The embedded circuit structure draws more and more attention than ever in order to pursue a thinner product, to meet the demands of finer wires and to overcome the drawbacks of the etching procedure and reliability. Because in the embedded circuit structure the wire pattern is embedded in the substrate, the thickness of the wires seems to be omitted, thereby further reducing the thickness of the products after packaging.

Currently, there are several methods available to form the circuit boards to meet the demand. The first one is to pattern the substrate by means of a laser fashion to define an intaglio structure. Then a conductive material is used to fill the recess formed on the substrate to obtain an embedded circuit structure.

Generally speaking, the surface of the substrate should be activated in the first place in order to let the conductive material successfully fill the recess on the substrate, usually by means of an electroless plating technique. As far as the current technical level is concerned, the circuit is directly designed. For example, the above-mentioned laser is used to pattern the substrate to define an intaglio-type structure, and then a conductive material is employed to fill the recess on the substrate to complete an embedded circuit structure.

Please refer to FIG. 1, which illustrates an over-plating by a current electroless plating technique. When an electroless plating technique is used to fill the recess 122 previously formed on a substrate 101 with a conductive material 130, first the over-plating occurs easily. Once the over-plating occurs, in one aspect the conductive material 130 extends to all directions along the corner of the opening of the recess. Since most attention is drawn to the development of fine wires, the pitch between wires on the same layer is as narrow as possible. The conductive material 130 which extends to all directions along the corner of the opening of the recess obviously makes two adjacent wires much more susceptible to short, and also makes the chemical agents less controllable. In another aspect, the conductive material 130 which is supposed to fill the recess 122 on a substrate 101 is more likely to attach to the surface of the substrate 101 to form undesirable contaminants, which makes the yield drop. Any one of the above problems is unwelcome in this art. As a result, there are still problems in this field to be overcome.

### SUMMARY OF THE INVENTION

The present invention therefore proposes a method for forming a circuit board structure of composite material. The method of the present invention is advantageous in selective deposition of electroless plating so that an over-plating is less likely to occur and the conductive material is less possible to extend to all directions along the corner of the opening of the recess. In addition, due to the selective deposition of electroless plating, the conductive material which is supposed to fill the recess on the substrate is less prone to attach onto the surface of the substrate, which makes the conductive material less susceptible to depositing on the incorrect regions on the surface of the substrate and makes the wires less likely to short.

The present invention first proposes a method for forming a circuit board structure of composite material. First, a composite material structure is provided. The composite material structure includes a substrate and a composite material dielectric layer disposed on the substrate. The composite material dielectric layer includes a catalyst dielectric layer contacting the substrate and a sacrificial layer contacting the catalyst dielectric layer. The sacrificial layer is insoluble in water. Later, the composite material dielectric layer is patterned and simultaneously catalyst particles in the catalyst dielectric layer are activated. Then, a conductive layer is formed on the activated catalyst particles. Afterwards, the sacrificial layer is removed. Preferably, the difference of the highest point and the lowest point on the conductive layer is less than 3 μm.

The present invention again proposes another method for forming a circuit board structure of composite material. First, a composite material structure is provided. The composite material structure includes a substrate and a composite material dielectric layer disposed on the substrate. The composite material dielectric layer includes a catalyst dielectric layer contacting the substrate, an inner sacrificial layer contacting the catalyst dielectric layer and an outer sacrificial layer contacting the inner sacrificial layer. The inner sacrificial layer is insoluble in water. Later, the composite material dielectric layer is patterned and simultaneously catalyst particles in the catalyst dielectric layer are activated. Afterwards, the outer sacrificial layer is removed. Then, a conductive layer is formed on the activated catalyst particles. Afterwards, the inner sacrificial layer is removed. Preferably, the difference of the highest point and the lowest point on the conductive layer is less than 3 μm.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates an over-plating by a current electroless plating technique.

FIGS. 2-7B illustrate a method for forming a circuit board structure of composite material of the present invention.

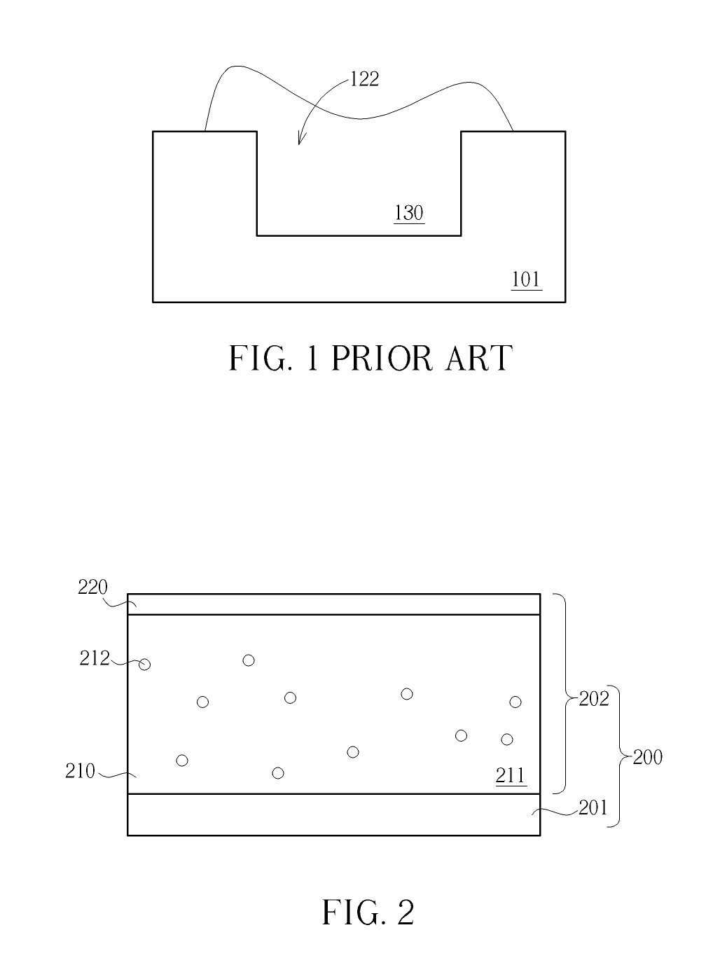

### DETAILED DESCRIPTION

The present invention provides a method for forming a circuit board structure of composite material. The composite material in the method of the present invention is advantageous in helping selective deposition of electroless plating so that an over-plating is less likely to occur on the composite material and the conductive material is less possible to extend to all directions along the corner of the opening of the recess. In addition, the conductive material which is supposed to fill the recess on the substrate is less prone to attach to the surface of the substrate, which makes the conductive material less susceptible to depositing on the incorrect regions on the surface of the substrate and makes the wires less likely to short.

The present invention accordingly provides a method for forming a circuit board structure of composite material. FIGS. 2-7B illustrate a method for forming a circuit board structure of composite material of the present invention. As shown in FIG. 2, a composite material structure 200 is first provided in the method for forming a circuit board structure of composite material of the present invention. The composite material structure 200 includes a substrate 201 and a composite material dielectric layer 202.

The substrate 201 in the composite material structure 200 of the present invention may be a multilayer circuit board, an embedded circuit structure circuit board and/or a non-embedded circuit structure circuit board for example. The composite material dielectric layer 202 is directly disposed on the substrate 201. The composite material dielectric layer 202 may include a catalyst dielectric layer 210 and a sacrificial layer 220. The catalyst dielectric layer 210 may include a dielectric material 211 and at least one catalyst particle 212. The catalyst particles 212 are dispersed in the dielectric material 211. Once activated, by laser for example, the catalyst particles 212 assist the catalyst dielectric layer 210 with inducing a conductive material to be deposited.

In one aspect, the dielectric material 211 in the composite material structure 200 of the present invention may be a polymeric material such as an epoxy resin, a modified epoxy resin, a polyester, an acrylate, a fluoropolymer, polyphenylene oxide, polyimide, a phenolic resin, polysulfone, poly silicon-containing material, bismaleimide triazine modified epoxy resin, cyanate polyester, polyethylene, polycarbonate, acrylonitrile-butadiene-styrene (ABS), polyethylene terephthalate(PET),polybutylene terephthalate (PBT), liquid crystal polyester (LCP), polyamide (PA), nylon-6, polyoxymethylene (POM), polyphenylene sulfide (PPS) and Cyclo olefin copolymer (COC) . . . etc.

In another aspect, the catalyst particles 212 in the composite material structure 200 of the present invention may include a plurality of nano-particles of a metal coordination compound, such as a metal oxide, a metal nitride, a metal complex, a metal chelate and the mixture thereof. The metal in the metal coordination compound may be Zn, Cu, Ag, Au, Ni, Pd, Pt, Co, Rh, Ir, In, Fe, Mn, Al, Cr, W, V, Ta and/or Ti.

The sacrificial layer 220 is on the outer surface of the composite material dielectric layer 202, or covering the catalyst dielectric layer 210. The sacrificial layer 220 maybe formed of an insulating material, such as polyimide, to form an insulating sacrificial layer. Optionally, the sacrificial layer 220 may be a single layer or multiple layers, with a thickness up to 25 μm. Embodiments are given to illustrate the sacrificial layer 220 to be a single layer or multiple layers.

If the sacrificial layer 220 is a single layer structure, as shown in FIG. 3, the entire composite material dielectric layer 202 is patterned. When the entire composite material dielectric layer 202 is patterned, a trench 225 is formed and simultaneously catalyst particles 212 are activated. The fashion to pattern the entire composite material dielectric layer 202 may be physical, such as by laser or by plasma etching. The laser may be an IR laser, UV laser, excimer laser or a far infrared laser.

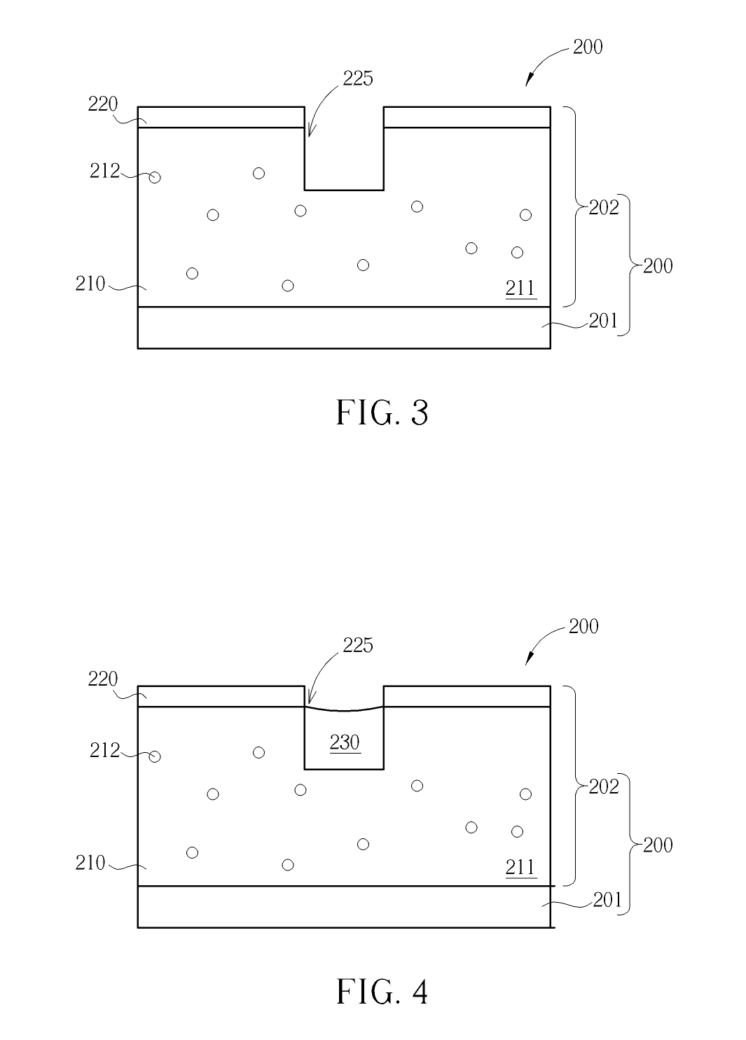

Then, as shown in FIG. 4 a conductive layer 230 is formed. The conductive layer 230 is embedded in the trench 225 of the composite material dielectric layer 202, so it is also on the activated catalyst particles 212. A conductive material, such as electroless copper, is filled in the trench 225 of the composite material dielectric layer 202, to form the conductive layer 230. By the induction of the activated catalyst particles 212, the conductive material is mainly deposited in the trench 225 rather than places other than the activated catalyst particles 212. The composite material of the present invention is advantageous in helping selective deposition of electroless plating on the surface of the activated trench 225 on the catalyst dielectric layer 210 so that the over-plating is less likely to occur and the conductive material is less possible to extend to all directions along the corner of the opening of the trench 225 when the composite material dielectric layer 202 is undergoing the electroless plating. In addition, the surface of the conductive layer 230 is much more smooth and flat. For example, the difference of the highest point and the lowest point on the conductive layer 230 is less than 3 μm.

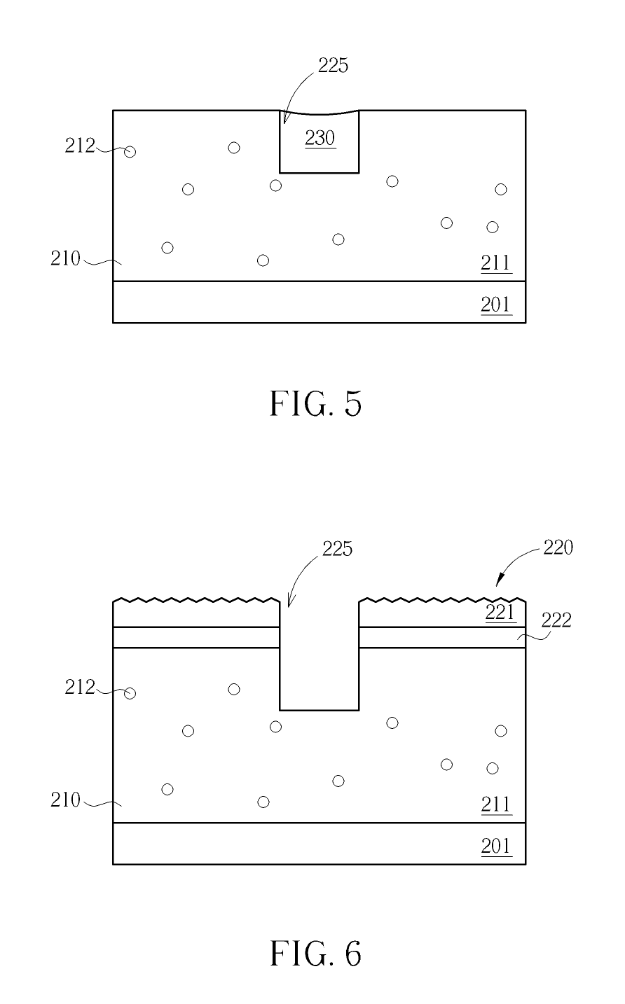

Because the texture of copper from a chemical process is not exactly the same as that from a plating process, the conductive layer 230 is preferably a single copper layer from an electroless process for example, rather than formed of copper of different physical properties, such as copper from electroless and electroplating process. The sacrificial layer 220 may be removed after the conductive layer 230 is formed, as shown in FIG. 5A. For example, the sacrificial layer 220 may be removed by peeling.

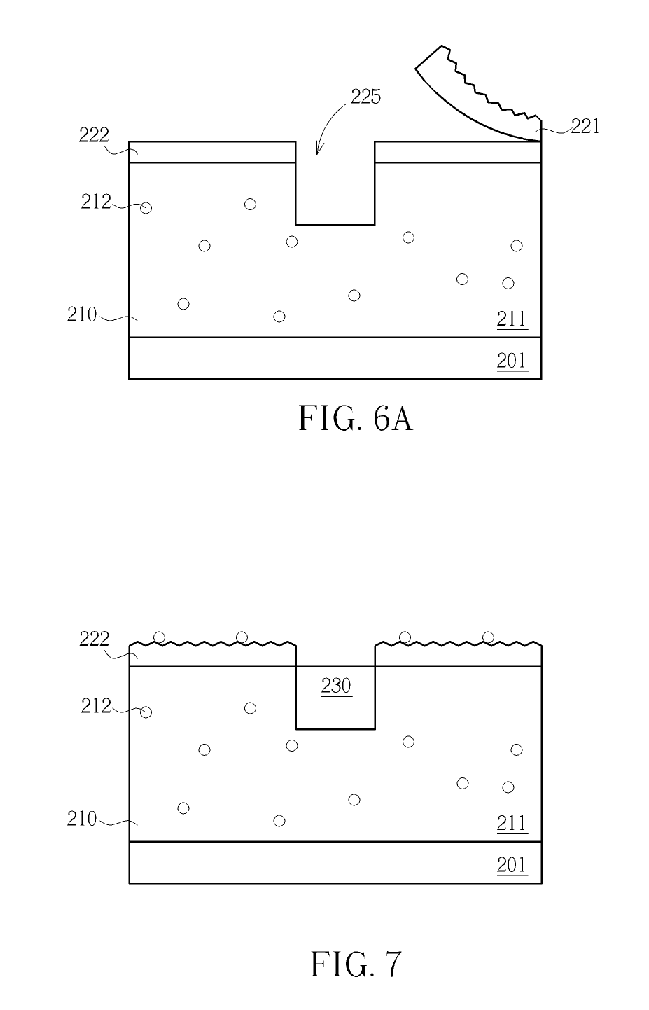

If the sacrificial layer 220 is multiple layers as shown in FIG. 6, the sacrificial layer 220 may include an inner sacrificial layer 221 and an outer sacrificial layer 222. The inner sacrificial layer 221 and the outer sacrificial layer 222 may be the same or different. For example, the inner sacrificial layer 221 is water-insoluble and the outer sacrificial layer 222 is not limited.

Afterwards, the entire composite material dielectric layer 202 is patterned. When the entire composite material dielectric layer 202 is patterned, a trench 225 is formed and simultaneously catalyst particles 212 are activated. The fashion to pattern the entire composite material dielectric layer 202 may be physical, such as by laser or by plasma etching. The laser may be an IR laser, UV laser, excimer laser or a far infrared laser.

If laser or plasma etching is used, the surface of the composite material dielectric layer 202 is damaged or residues are left on the surface of the composite material dielectric layer 202 during the patterning of the composite material dielectric layer 202, both of which may interfere with the induction of the conductive material by the catalyst particles 212 into the trench 225. If it is the case, the outer sacrificial layer 221 is removed to solve the problem completely. The outer sacrificial layer 221 maybe removed after the material dielectric layer 202 is patterned, as shown in FIG. 6A so that the surface of the composite material dielectric layer 202 is clean again.

The outer sacrificial layer 221 is soluble in water, the outer sacrificial layer 221 may be removed after the material dielectric layer 202 is patterned and before the conductive layer 230 is formed to avoid any residues from the patterning of the material dielectric layer 202 interfering with the formation of the conductive layer 230. The outer sacrificial layer 221 may include hydrophilic polymers to be washed off when needed. The functional groups of the hydrophilic polymers may include any one of —OH, —CONH₂, —SO₃H and —COOH or the combination thereof. If the outer sacrificial layer 221 is water-insoluble, the outer sacrificial layer 221 may be removed by peeling.

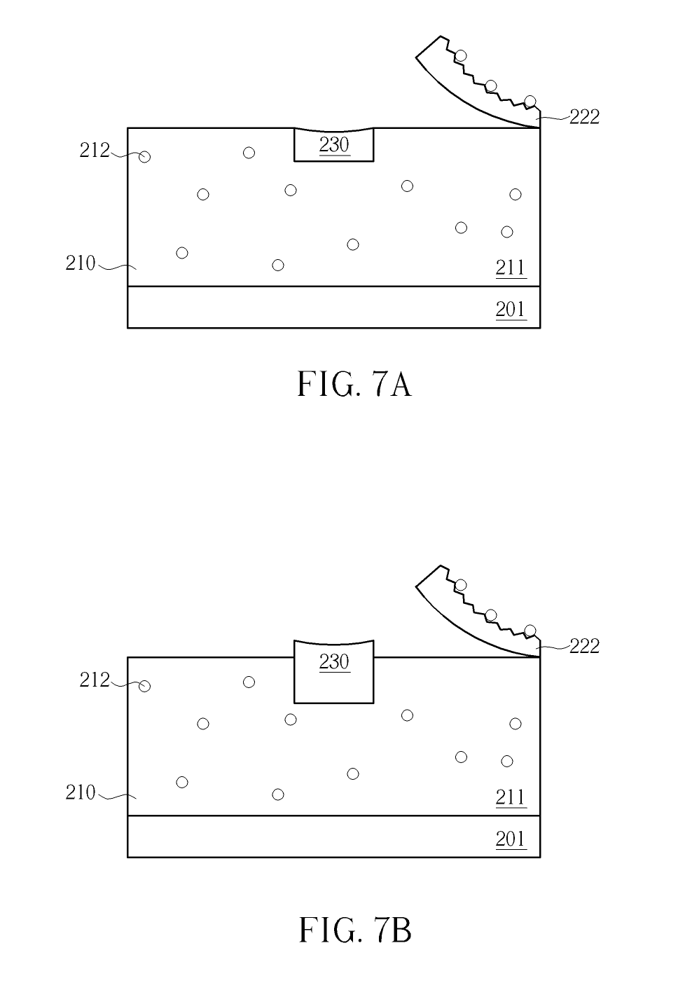

Then, as shown in FIG. 7a conductive layer 230 is formed. The conductive layer 230 is selectively deposited on the surface of the activated catalyst dielectric layer, so it is on the catalyst dielectric layer 210. If the surface of the material dielectric layer 202 is clean again, a conductive material, such as electroless copper, is filled in the trench 225 of the composite material dielectric layer 202. The activated catalyst particles 212 easily induce the conductive material to deposit in the trench 225 without outside interference when the conductive layer 230 is formed. In addition, the surface of the conductive layer 230 is much more smooth and flat. For example, the difference of the highest point and the lowest point on the conductive layer 230 is less than 3 μm.

The composite material in the method of the present invention is advantageous in helping the conductive material selectively not formed on the regions with no activated catalyst particles 212 so the over-plating is less likely to occur and the conductive material is less possible to extend to all directions along the corner of the opening of the trench 225 when the material dielectric layer 202 is undergoing electroplating.

Because the texture of copper from a chemical process is not exactly the same as that from a plating process, preferably the conductive layer 230 is structurally a single copper layer from an electroless process for example, rather than formed of copper of different physical properties, such as copper from electroless and electroplating process.

Depending on the process, the conductive layer 230 may be as thick as the dielectric material 211, as shown in FIG. 7A. Or, alternatively, the conductive layer 230 is slightly thicker than the dielectric material 211, as shown in FIG. 7B. For example, for the conductive layer 230 on the same substrate 201, some may be slightly thicker than the dielectric material 211 and some may be as thick as the dielectric material 211. The inner sacrificial layer 222 may be removed after the conductive layer 230 is formed, as shown in FIG. 7B. For example, the inner sacrificial layer 222 may be removed by peeling.

Those skilled in the art will readily observe that numerous modifications and alterations of the device and method may be made while retaining the teachings of the invention.

What is claimed is:

1. A method for forming a circuit board structure of composite material, the method comprising:
providing a composite material structure comprising a substrate and a composite material dielectric layer disposed on said substrate, said composite material dielectric layer comprising:
a catalyst dielectric layer contacting said substrate and comprising catalyst particles; and
a sacrificial layer which contacts said catalyst dielectric layer and is water-insoluble;
patterning said composite material dielectric layer and activating said catalyst particles;
forming a conductive layer on said activated catalyst particles; and
removing said sacrificial layer.

2. The method for forming a circuit board structure of composite material of claim 1, wherein said substrate comprises an embedded circuit structure circuit board.

3. The method for forming a circuit board structure of composite material of claim 1, wherein said catalyst dielectric layer comprises a dielectric material and said catalyst particles.

4. The method for forming a circuit board structure of composite material of claim 1, wherein said catalyst particles comprise a plurality of nano-particles.

5. The method for forming a circuit board structure of composite material of claim 1, wherein the material of said catalyst particles comprises a metal coordination compound, wherein said metal coordination compound is selected from a group consisting of a metal oxide, a metal nitride, a metal complex, a metal chelate and the mixture thereof.

6. The method for forming a circuit board structure of composite material of claim 1, wherein said conductive layer is embedded in said composite material dielectric layer.

7. The method for forming a circuit board structure of composite material of claim 1, wherein the difference of the highest point and the lowest point on said conductive layer is less than 3 μm.

8. The method for forming a circuit board structure of composite material of claim 1, wherein said conductive layer consists of a single copper layer.

9. The method for forming a circuit board structure of composite material of claim 1, wherein said conductive layer is formed by an electroless copper process.

10. The method for forming a circuit board structure of composite material of claim 1, wherein said sacrificial layer covers said catalyst dielectric layer.

11. A method for forming a circuit board structure of composite material, the method comprising:
providing a composite material structure comprising a substrate and a composite material dielectric layer disposed on said substrate, said composite material dielectric layer comprising:
a catalyst dielectric layer contacting said substrate and comprising catalyst particles;
an inner sacrificial layer which contacts said catalyst dielectric layer and is water-insoluble; and
an outer sacrificial layer contacting said inner sacrificial layer;
patterning said composite material dielectric layer and activating said catalyst particles;
removing said outer sacrificial layer;
forming a conductive layer on said activated catalyst particles; and
removing said inner sacrificial layer.

12. The method for forming a circuit board structure of composite material of claim 11, wherein said substrate comprises an embedded circuit structure circuit board.

13. The method for forming a circuit board structure of composite material of claim 11, wherein said catalyst dielectric layer comprises a dielectric material and said catalyst particles.

14. The method for forming a circuit board structure of composite material of claim 11, wherein said catalyst particles comprise a plurality of nano-particles.

15. The method for forming a circuit board structure of composite material of claim. 11, wherein the material of said catalyst particles comprise a metal coordination compound, wherein said metal coordination compound is selected from a group consisting of a metal oxide, a metal nitride, a metal complex, a metal chelate and the mixture thereof.

16. The method for forming a circuit board structure of composite material of claim 11, wherein said conductive layer is embedded in said composite material dielectric layer.

17. The method for forming a circuit board structure of composite material of claim 11, wherein the difference of the highest point and the lowest point on said conductive layer is less than 3 μm.

18. The method for forming a circuit board structure of composite material of claim 11, wherein said conductive layer consists of a single copper layer.

19. The method for forming a circuit board structure of composite material of claim 11, wherein said conductive layer is formed by a chemical copper process.

20. The method for forming a circuit board structure of composite material of claim 11, wherein said inner sacrificial layer and said outer sacrificial layer are made of a same material.

21. The method for forming a circuit board structure of composite material of claim 11, wherein said inner sacrificial layer and said outer sacrificial layer are made of different materials, wherein said outer sacrificial layer comprises a water-soluble material.

22. The method for forming a circuit board structure of composite material of claim 11, wherein said inner sacrificial layer covers said catalyst dielectric layer.
